(19) United States
(12) Patent Application Publication
(10) Pub. No.: US 2016/0342018 A1
(43) Pub. Date: Nov. 24, 2016

(54) Manufacturing Method of a Color Filter Substrate

(71) Applicant: SHENZHEN CHINA STAR OPTOELECTRONICS TECHNOLOGY CO., LTD., Shenzhen, Guangdong (CN)

(72) Inventors: Jingfeng XUE, Shenzhen, Guangdong (CN); Gui CHEN, Shenzhen, Guangdong (CN)

(73) Assignee: Shenzhen China Star Optoelectronics Technology Co., Ltd., Shenzhen, Guangdong (CN)

(21) Appl. No.: 14/422,660

(22) PCT Filed: Jan. 16, 2015
(86) PCT No.: PCT/CN2015/070891

§ 371 Date: Feb. 19, 2015

(30) Foreign Application Priority Data
Dec. 30, 2014 (CN) 201410844602.5

(51) Int. Cl. G02F 1/1335; G03F 7/16; G03F 7/20; G03F 7/32; G02B 5/20; G03F 7/00

(52) U.S. Cl. CPC G02F 1/133516; G02B 5/201; G02F 1/133512; G03F 7/0007; G03F 7/20; G03F 7/32; G03F 7/16; G02F 2001/133519

(57) ABSTRACT

The present invention discloses a manufacturing method of a color filter substrate, comprises steps of: providing a substrate; forming a light-shielding portion on the substrate; forming a color filter on the substrate, wherein, the color filter comprises a color portion and a opening portion; covering a planarization layer on the substrate, and the planarization layer is filled in the opening portion; performing a photolithography process to the planarization layer; forming a interval body on the planarization layer after the photolithography process. In the present invention, a transparent photoresist layer is applied to fill in the opening portion as the white photoresist and a surface of the transparent photoresist layer is planarized by utilizing photolithography process; compared with the technology in the art, when waiving a manufacturing process of photolithography process for white photoresists, the transparent photoresist layer at the opening portion is not dented.

### FIELD OF THE INVENTION

The present invention relates to a manufacturing method of a color filter substrate, and particularly to planarize a surface of the planarization layer by using a photolithography process technique.

### BACKGROUND OF THE INVENTION

A liquid crystal display panel comprises an upper substrate and a lower substrate disposed corresponding to each other and a liquid crystal layer disposed between the upper substrate and the lower substrate. The upper substrate is usually called a color filter (CF) substrate and the lower substrate is usually called an array substrate. Various demandings for liquid crystal display panels are increasing with information technical development, wherein, high transmissivity, low energy consumption and good imaging quality are became demandings of display panels to human beings. To achieve these demandings, a liquid crystal panel of a pixel comprised by red (R) sub-pixel, green (G) sub-pixel, blue (B) sub-pixel and white (W) sub-pixel is produced; thus is, the pixel is comprised by the red (R) sub-pixel, the green (G) sub-pixel, the blue (B) sub-pixel and the white (W) sub-pixel in the color filter substrate.

The color filter substrate has various manufacturing methods, for example, one of the manufacturing methods is forming red, green, blue and white photoresists on the substrate, and then forming a planarization layer on the substrate; however, a photolithography process with the white photoresist is added in this manufacturing method. Another manufacturing method is forming red, green and blue photoresists on a substrate and the same materials of color photoresists with the planarization layer, and then further forming a planarization layer on the substrate; however, a photolithography process with the same materials of color photoresists with the planarization layer is added in this manufacturing method.

Another further manufacturing method is forming red, green and blue photoresists on a substrate and a opening portion, and then the planarization layer is filled in the opening portion; however, although the photolithography process is waived in this manufacturing method, a dent at the planarization layer is appeared on the opening portion to have a surface of the planarization layer rough and uneven and then further affect display qualities in liquid crystal display panel after manufacturing.

### SUMMARY OF THE INVENTION

In order to solve the existing problems in the present technology described above, an objective of the present invention is to provide a manufacturing method of a color filter substrate, and the steps comprise:

providing a substrate;

forming a light-shielding portion on the substrate;

forming a color filter on the substrate, wherein, the color filter comprises a color portion and an opening portion;

covering a planarization layer on the substrate, and the planarization layer is filled in the opening portion;

performing a photolithography process to the planarization layer;

forming a transparent electrode layer on the planarization layer of the post-photolithography process;

forming an interval body on the transparent electrode layer. Further, before forming the interval body on the planarization layer of the post-photolithography process, forming a transparent electrode layer on the planarization layer of the post-photolithography process, and then further forming the interval body on the transparent electrode layer. Further, the planarization layer is a transparent negative photoresist layer. Further, a Half Tone Mask used for exposing the planarization layer is utilized in performing the photolithography process to the planarization layer, and then further performing development to the post-exposed planarization layer to planarize a surface of the post-development planarization layer. Further, a Gray Tone Mask used for exposing the planarization layer is utilized in performing the photolithorgraphy process to the planarization layer, and then further performing development to the post-exposed planarization layer to planarize a surface of the post-development planarization layer. Further, the color portion comprises a red portion, a green portion, and a blue portion. Further, a material of the light-shielding portion is a chromium metal or a black resin. Further, a red photoresist is formed on a surface of the substrate by using spin-coating technique in the color portion, and then further the red photoresist in a red pixel predetermined region is left and the red photoresist in other region is removed then by performing development.

Further, the color portion further comprises a green photoresist and a blue photoresist both formed in sequence in the same manner.

Further, a material of the transparent electrode layer is Indium-Tin Oxide (ITO). Further, the interval body is formed by coating a negative photoresist material and then further by a lithography process.

In the present invention, a transparent photoresist layer is applied to fill in the opening portion as the white photoresist and a surface of the transparent photoresist layer is planarized by utilizing photolithography process; compared with the technology in the art, when waiving a manufacturing process of photolithography process for white photoresists, the transparent photoresist layer at the opening portion is not dented and display qualities of the liquid crystal panel during manufacturing is further increased.

### BRIEF DESCRIPTION OF THE DRAWINGS

Other aspects, features and advantages of embodiments of the present invention will be even more apparent from the following detailed description taken in connection to the accompanying drawings. In the drawings:

FIG. 1A-1E are schematic diagrams representing a manufacturing method of the color filter substrate according to a first embodiment of the present invention;

FIG. 2E is schematic diagram representing a method of forming the interval body according to a second embodiment of the present invention;

FIG. 3D is schematic diagram representing a method of performing the photolithography process to the transparent photoresist layer according to a third embodiment of the present invention.

### DETAILED DESCRIPTION OF THE INVENTION

Hereinafter, detailed descriptions will be set forth for embodiments of the invention in conjunction with the accompanying drawings. However, there are many different ways to perform the present invention, and the present invention should not be explained to limit the described embodiment hereinafter. On the contrary, these provided embodiments are for explain principles and the practical applications of the present invention for those skilled in the art to understand various embodiments of the present invention and various modifications of properly specific expectations. In drawings, like reference numerals refer to like elements throughout.

### The First Embodiment

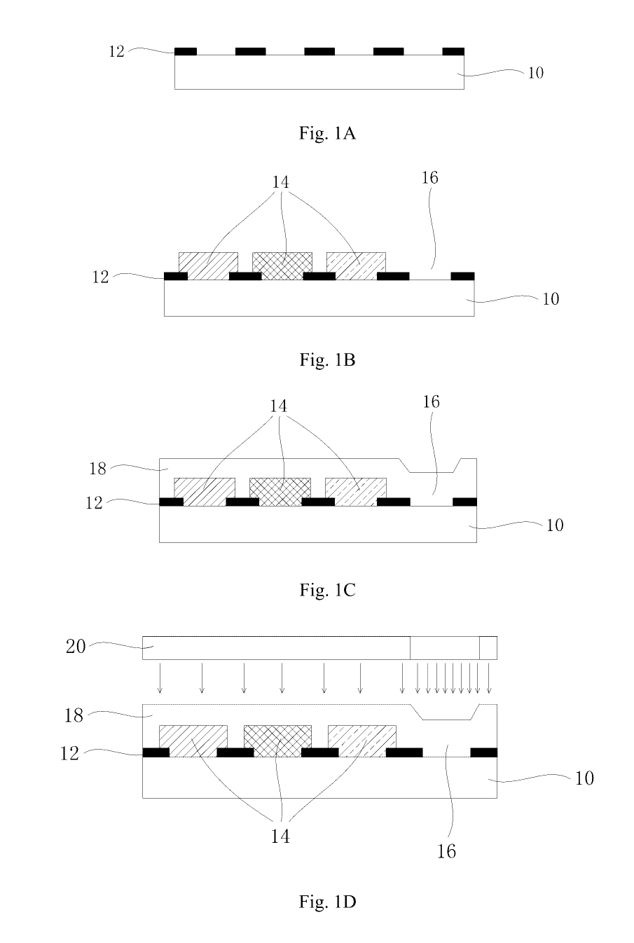

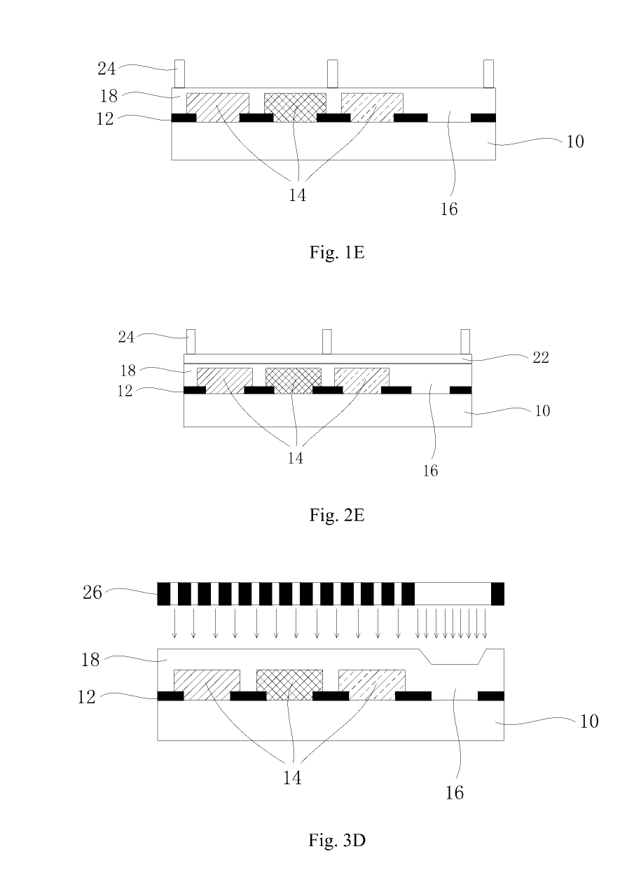

FIG. 1A-1E are schematic diagrams representing a manufacturing method of the color filter substrate according to a first embodiment of the present invention. In the first embodiment, a display model of the liquid crystal display panel comprising the color filter substrate can be, ex: a vertical alignment (VA) model or a twisted nametic (TN) display model.

Firstly, please refer to FIG. 1A, providing a substrate 10, for example: a insulating transparent substrate which is defined as a color filter substrate is usually called a upper substrate; next, a light-shielding portion 12 of black matrix is formed on the substrate 10, wherein, a material of the shielding portion 12 of black matrix can be a black resin or a chromium metal; for example, a certain thickness of the black resin is manufactured by Lithography Process, and preferably the material is a macromolecular material comprising of acrylic and carbon; also a certain thickness of the chromium metal is manufactured in the same manner, and a red photoresist, a green photoresist, a the blue photoresist are not laminated each other because of a thinner thickness.

Next, please refer to FIG. 1B, a color filter is formed on the substrate 10, wherein, the color filter comprises a color photoresist portion 14 including a red photoresist, a blue photoresist, and a green photoresist and an opening portion 16; the red photoresist of the color photoresist portion 14 is manufactured by using spin-coating technique or other methods to form a red pigment photoresist on a surface of the substrate 10, and then further a certain thickness of the red photoresist in a red pixel predetermined region is left and the red photoresist in other region is removed by performing exposure and development. And then the same thinkness of a green photoresist and the same thickness of a blue photoresist both formed in sequence in the same manner.

Next, please refer to FIG. 1C, a certain thickness of the transparent photoresist layer 18 is deposited and covered on the color filter by using spin-coating technique or other methods, wherein, the transparent photoresist layer 18 is applied to fill in the opening portion 16, and the transparent photoresist layer 18 is a negative transparent photoresist layer formed with transparent photosensitive material or heat-sensitive material.

Next please refer to FIG. 1D, a surface the transparent photoresist layer 18 is planarized by utilizing photolithography process, and a Half Tone Mask (HTM) 20 used for exposing the transparent photoresist layer 18 is utilized in performing the photolithography process to the transparent photoresist layer 18, and then further performing development to the post-exposed transparent photoresist layer 18 to planarize the surface of the post-development transparent photoresist layer 18. Herein, the corresponding opening portion 16 of a Half Tone Mask 20 has a higher transmittance, and the rest has lower transmittance, wherein, a downward pointing arrow represents the light passing through the Half Tone Mask 20.

Due to the transparent photoresist layer 18 is negative transparent photoresist layer, a part of the photoresist accepted intense illumination remains more after performing development, but the rest of the photoresist accepted weak light remains less after performing development. Thus, the transparent photoresist layer 18 is applied exposure by a Half Tone Mask 20, and then the transparent photoresist layer 18 on the red photoresist, the blue photoresist, and the green photoresist of the color photoresist portion 14 is removed more after performing development. On the other hand, the transparent photoresist layer 18 of the opening portion 16 is removed less so as to the surface of the post-development transparent photoresist layer 18 is a planarization.

Finally, please refer to the FIG. 1E, a negative photophotoresist material, ex: acrylic, is coated on a electrode layer 22 firstly, and then a column-like interval body 24 is left by performing a Lithography Process to hold an interval between the upper substrate and the lower substrate of the liquid crystal display panel. It should be noted that, because the surface of the transparent photoresist layer 18 is planarized, the film thickness of interval body 24 is evener.

### The Second Embodiment

According to the second embodiment of the present invention, the method before forming the interval body 24 is equivalent to the first embodiment, thus the method before forming the interval body 24 in the second embodiment can refer to FIG. 1A to FIG. 1D. Herein, not be described in any great detail, only the differences of the method to form the interval body 24 from the first embodiment are described in the second embodiment.

Firstly, it should also be noted that a display model of the liquid crystal display panel comprising the color filter substrate in the second embodiment can be, ex: a fringe field switching (FFS) model or a in plane switching (IPS) display mode.

FIG. 2E is schematic diagram representing a method of forming the interval body according to a second embodiment of the present invention.

Refer to FIG. 2E, after the surface of the transparent photoresist layer 18 is planarized to facilitate subsequent deposition of the electrode layer 22 on the transparent photoresist layer 18 , wherein, the electrode layer 22 is can be, ex: a transparent conductive film of Indium-Tin Oxide (ITO).

Next, keep referring to FIG. 2E, a negative photoresist material, ex: acrylic, is coated on a electrode layer 22 firstly, and then a column-like interval body 24 is left by performing a Lithography Process to hold an interval between the upper substrate and the lower substrate of the liquid crystal display panel. It should be noted that, because the surface of the transparent photoresist layer 18 is planarized, the film thickness of interval body 24 is evener. FIG. 3D is schematic diagram representing a method of performing the photolithography process to the transparent photoresist layer according to a third embodiment of the present invention.

According to the third embodiment of the present invention, except distinguish from performing the method of the photolithography process for transparent photoresist layer illustrated in FIG. 3D and performing the method of the photolithography process for transparent photoresist layer illustrated in FIG. 1D, the other methods are all the same so as will not be described in any great detail of both.

Please refer to FIG. 3D, according to another embodiment of the present invention, a Gray Tone Mask (GTM) 26 used for performing exposure to the transparent photoresist layer 18 is utilized in performing the photolithorgraphy process to the transparent photoresist layer 18 and then further performing development to the post-exposed transparent photoresist layer 18 to planarize a surface of the post-development transparent photoresist layer 18. Herein, the corresponding opening portion 16 of a Gray Tone Mask 26 has a higher transmittance, and the rest has lower transmittance, wherein, a downward pointing arrow represents the light passing through the Gray Tone Mask 26. Due to the transparent photoresist layer 18 is negative transparent photoresist layer, a part of the photoresist accepted intense illumination remains more after performing development, but the rest of the photoresist accepted weak light remains less after performing development. Thus, the transparent photoresist layer 18 is applied exposure by a Gray Tone Mask 26, and then the transparent photoresist layer 18 on the red photoresist, the blue photoresist, and the green photoresist of the color photoresist portion 14 is removed more after performing development. On the other hand, the transparent photoresist layer 18 of the opening portion 16 is removed less so as to the surface of the post-development transparent photoresist layer 18 is a planarization.

In view of the foregoing, in the present invention, a transparent photoresist layer is applied to fill in the opening portion as the white photoresist and a surface of the transparent photoresist layer is planarized by utilizing photolithography process; compared with the technology in the art, when waiving a manufacturing process of photolithography process for white photoresists, the transparent photoresist layer at the opening portion is not dented and display qualities of the liquid crystal panel during manufacturing is further increased.

While the invention has been shown and described with reference to certain exemplary embodiments thereof, it will be understood by those skilled in the art that various changes in form and details may be made therein without departing from the spirit and scope of the invention as defined by the appended claims and their equivalents.

1. A manufacturing method of a color filter substrate, wherein, comprises steps of:
providing a substrate;
forming a light-shielding portion on the substrate;
forming a color filter on the substrate, wherein, the color filter comprises a color portion and a opening portion;
covering a planarization layer on the substrate, and the planarization layer is filled in the opening portion;
performing a photolithography process to the planarization layer;
forming an interval body on the planarization layer after the photolithography process.

2. The manufacturing method according to the claim 1, wherein, before forming the interval body on the planarization layer of the post-photolithography process, forming a transparent electrode layer on the planarization layer of the post-photolithography process, and then further forming the interval body on the transparent electrode layer.

3. The manufacturing method according to the claim 1, wherein, the planarization layer is a transparent negative photoresist layer 4. The manufacturing method according to the claim 2, wherein, the planarization layer is a transparent negative photoresist layer.

4. The manufacturing method according to the claim 1, wherein, a Half Tone Mask used for exposing the planarization layer is utilized in performing the photolithography process to the planarization layer, and then further performing development to the post-exposed planarization layer to planarize a surface of the post-development planarization layer.

5. The manufacturing method according to the claim 2, wherein, a Half Tone Mask used for exposing the planarization layer is utilized in performing the photolithography process to the planarization layer, and then further performing development to the post-exposed planarization layer to planarize a surface of the post-development planarization layer.

6. The manufacturing method according to the claim 1, wherein, a Gray Tone Mask used for exposing the planarization layer is utilized in performing the photolithorgraphy process to the planarization layer, and then further performing development to the post-exposed planarization layer to planarize a surface of the post-development planarization layer.

7. The manufacturing method according to the claim 2, wherein, a Gray Tone Mask used for exposing the planarization layer is utilized in performing the photolithorgraphy process to the planarization layer, and then further performing development to the post-exposed planarization layer to planarize a surface of the post-development planarization layer.

8. The manufacturing method according to the claim 1, wherein, the color portion comprises a red portion, a green portion, and a blue portion.

9. The manufacturing method according to the claim 2, wherein, the color portion comprises a red portion, a green portion, and a blue portion.

10. The manufacturing method according to the claim 1, wherein, a material of the light-shielding portion is a chromium metal or a black resin.

11. The manufacturing method according to the claim 2, wherein, a material of the light-shielding portion is a chromium metal or a black resin.

12. The manufacturing method according to the claim 1, wherein, a red photoresist is formed on a surface of the substrate by using spin-coating technique in the color portion, and then further the red photoresist in a red pixel predetermined region is left and the red photoresist in other region is removed then by performing exposure and development.

13. The manufacturing method according to the claim 2, wherein, a red photoresist is formed on a surface of the substrate by using spin-coating technique in the color portion, and then further the red photoresist in a red pixel predetermined region is left and the red photoresist in other region is removed then by performing exposure and development.

14. The manufacturing method according to the claim 13, wherein, the color portion further comprises a green photoresist and a blue photoresist both formed in sequence in the same manner.

15. The manufacturing method according to the claim 14, wherein, the color portion further comprises a green photoresist and a blue photoresist both formed in sequence in the same manner.

16. The manufacturing method according to the claim 1, wherein, the interval body is formed by coating a negative photoresist material and then further by a to lithography process.

17. The manufacturing method according to the claim 1, wherein, the interval body is formed by coating a negative photoresist material and then further by a lithography process.
